(19) United States
(12) Patent Application Publication
(10) Pub. No.: US 2017/0263472 A1
(43) Pub. Date: Sep. 14, 2017

(54) MULTIPLE WAFER ROTARY PROCESSING

(71) Applicant: APPLIED Materials, Inc., Santa Clara, CA (US)

(72) Inventors: John L. Klocke, Kalispell, MT (US); Kyle M. Hanson, Kalispell, MT (US); Joseph A. Jonathan, Kalispell, MT (US); Stuart Crane, Kalispell, MT (US)

(21) Appl. No.: 15/441,081

(22) Filed: Feb. 23, 2017

Related U.S. Application Data
(60) Provisional application No. 62/305,376, filed on Mar. 8, 2016.

(51) Int. Cl. H01L 21/67; B08B 3/02; B08B 3/08; B08B 3/04; H01L 21/687; B08B 3/12

(52) U.S. Cl. CPC H01L 21/67057; H01L 21/68764; H01L 21/68771; B08B 3/123; B08B 3/08; B08B 3/041; B08B 3/022

(57) ABSTRACT

A wafer processor has a rotor holding wafers within a process tank. The rotor rotates sequentially moving the wafers through a process liquid held in the process tank. The tank may have an I-beam shape to reduce the volume of process liquid. A load port is provided at a top of the process tank for loading and unloading wafers into and out of the process tank. Rinsing and cleaning chambers may be associated with the load port to remove process liquid from processed wafers. The processor may be oriented with the rotor rotating about a horizontal axis or about a vertical axis.

### PRIORITY CLAIM

This application claims priority to U.S. Provisional Patent Application No. 62/305,376, filed Mar. 8, 2016, and now pending.

### SUMMARY OF INVENTION

This application relates to processors, systems, and methods for processing semiconductor material wafers, and similar workpieces or substrates for microelectronic devices.

### BACKGROUND OF THE INVENTION

Microelectronic devices, such as semiconductor devices, are generally fabricated on and/or in semiconductor material wafers. Patterned layers are formed on the wafer surface via photolithography. Photoresist used in the photolithography steps is removed by chemical stripping. This may be a relatively time consuming process, especially with wafers having thicker layers of photoresist, or hardened photoresist that is not quickly removable with available process liquids, such as solvents.

To speed up the manufacturing process, wafers are often processed in batches, typically with multiple wafers processed while held in a tray, cassette or similar holder. While batch processing can operate at high throughput or processing rates, it can be difficult to consistently achieve desired results because the wafers are not uniformly exposed to process liquids. For example, wafers in the middle of the batch may not be directly exposed to sprays of process liquids. Single wafer processing, on the other hand largely achieves uniform processing, but at lower throughput rates in comparison to batch processing.

Accordingly, engineering challenges remain in providing systems and methods for processing wafers, especially relative to more time consuming process steps.

### SUMMARY OF THE INVENTION

A wafer processor has a rotor holding wafers within a process tank. The rotor rotates sequentially moving the wafers through a process liquid held in the process tank. The tank may have an I-beam shape to reduce the volume of process liquid needed for processing. A load port is provided at a top of the process tank for loading and unloading wafers into and out of the process tank. Rinsing and cleaning chambers may be associated with the load port to remove process liquid from the processed wafers. The rotor may be oriented to rotate about a substantially horizontal axis or about a substantially vertical axis.

### BRIEF DESCRIPTION OF THE DRAWINGS

In the drawings:

FIG. 1 is a perspective view of processing system.

FIG. 2 is a side view of the system shown in FIG. 1.

FIG. 3 is a perspective view of the tank of the system shown in FIGS. 1 and 2.

FIG. 4 is a section view taken along line 4-4 of FIG. 3.

FIG. 5 is a perspective view of the head shown in FIGS. 1 and 2.

FIG. 6 is a side view of an alternative embodiment.

### DETAILED DESCRIPTION

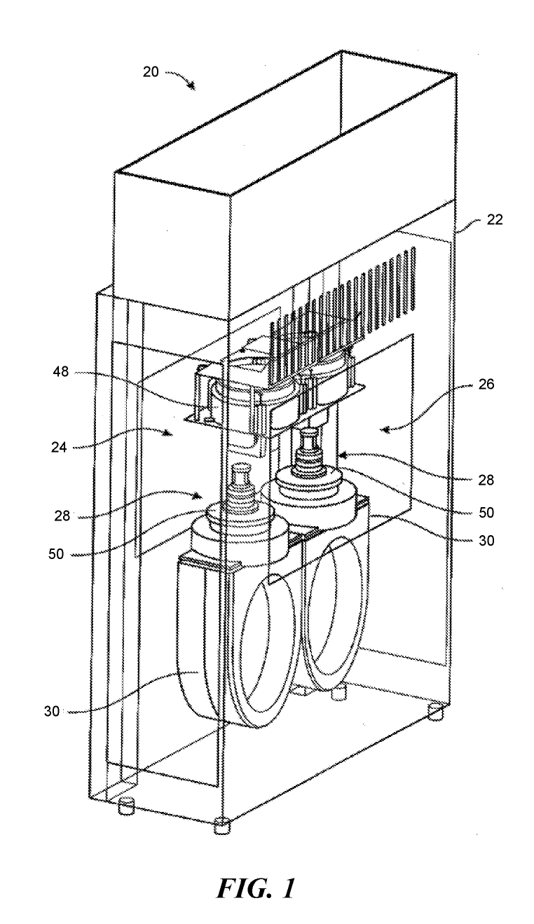

As shown in FIG. 1, a processing system 20 has first and second wafer processors 28 within an enclosure 22. The enclosure 22 may have access openings 24 and 26 to allow workpieces, such as semiconductor wafers, to be moved into and out of the processing system 20, typically via robots. The access openings 24 and 26 may have closures, such as movable panels or windows, for closing off the access openings 24 and 26 during processing, to better contain vapors or gases within the enclosure 22. The enclosure 22 may also be provided with air inlets and exhaust connections, to provide a controlled flow of air through the enclosure.

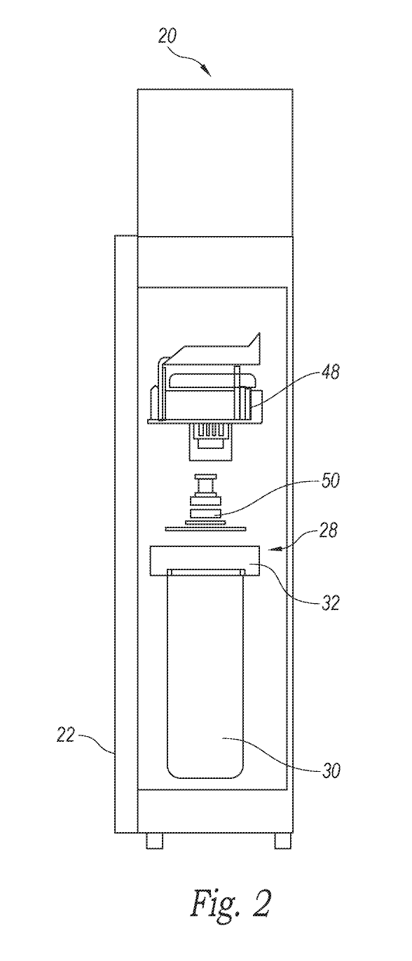

As shown in FIGS. 1 and 2, each processor 28 has a head 50 for loading wafers 100 into and out of a process tank 30. Depending on the specific process performed, a secondary chamber 48, such as a spin rinser dryer, may be associated with each processor 28 within the enclosure.

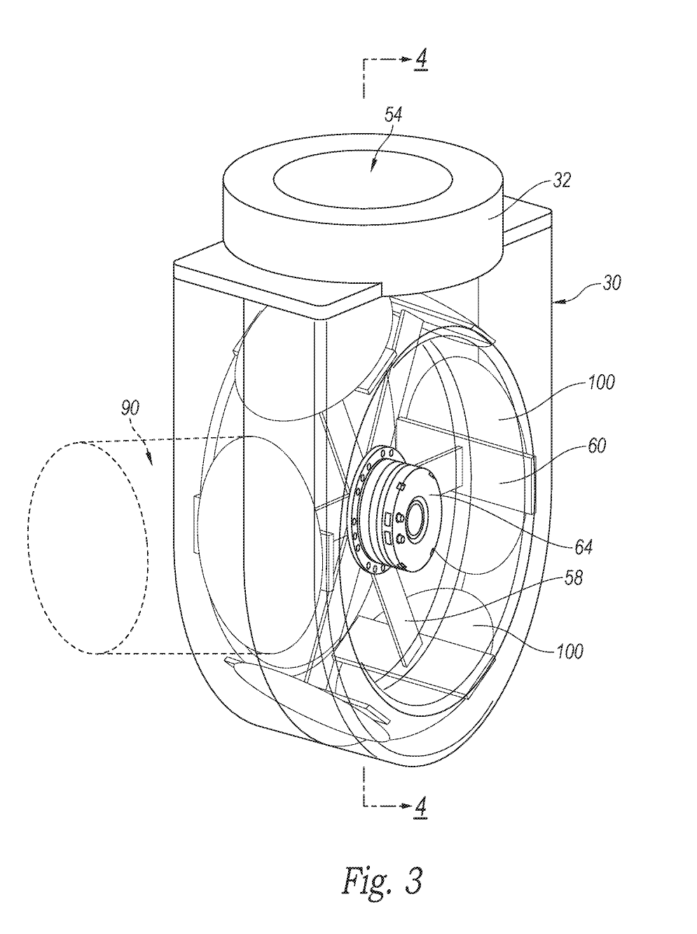

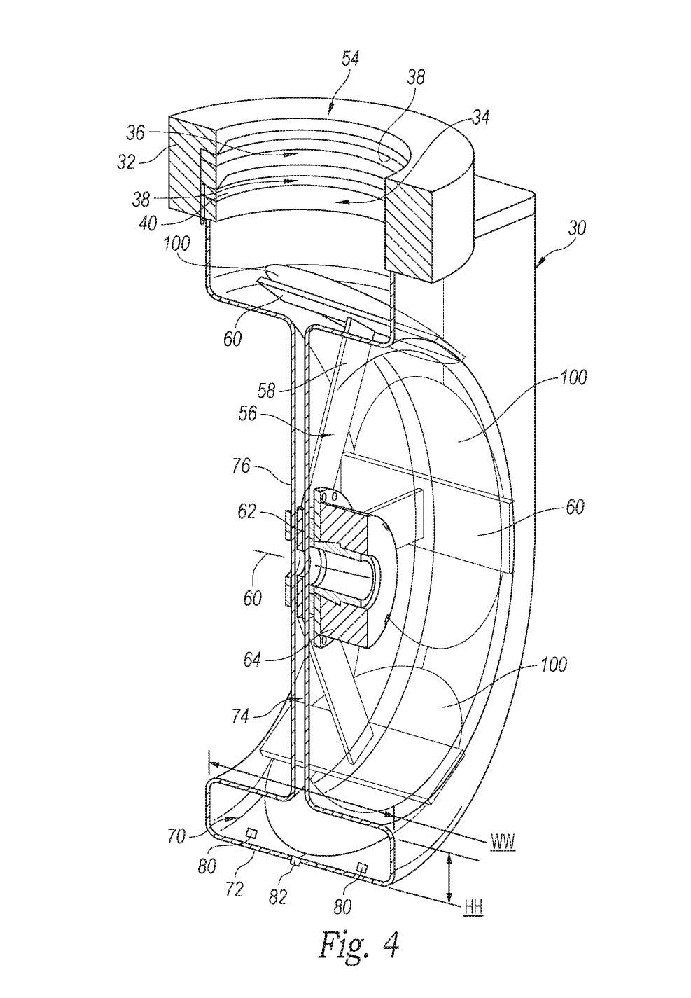

Turning now to FIGS. 3 and 4, a clean housing 32 is provided at the top of the process tank 30. The clean housing 32, if used, generally includes clean chamber 34 surrounded by a lower or clean chamber drain channel 40, and a rinse chamber 36 surrounded by an upper or rinse chamber drain channel 38. The drain channels 38 and 40 are connected to a facility drain and optionally to a vacuum source. The process tank also includes one or more liquid inlets and one or more liquid drains, for filling and draining the process liquid, or providing a flow of process liquid through the process tank.

As best shown in FIG. 4, the process tank 30 has a ring section 70 wide enough to accommodate a wafer 100, and a much narrower central web section 76. A rotor 56 has a plurality of arms 58 extending radially outward from a central hub 62, with a holder 60 at the outer end of each arm 58. A motor 64 is connected to the rotor 56 for rotating the rotor 56 in the process tank 30. The process tank 30 in the example of FIG. 4 has an I-shaped cross section, to allow wafers 100 on the rotor 56 to be fully immersed in process liquid as the rotor 56 rotates the wafers through the tank 30. The ring section 70 has a circumferential outer wall 72, typically subtending an arc of at least 270 degrees. One or more liquid nozzles 80 and/or sonic transducers 82 may be provided on or in the outer wall 72. The arms 58 are typically flat and narrow to fit within the arm space or slot 74 in the web section 76.

In use, a process liquid, such as a solvent, is pumped into the process tank 30 so that the process tank 30 is filled to e.g., 50 to 90% of capacity. The head 50 holding a wafer 100 is lowered down into a load port 54 at the top of the process tank 30. The head 50 hands the wafer 100 off to a holder 60 on the rotor 56. The holder 60 engages the backside and/or edge of the wafer 100, with the front or device side of the wafer 100 facing up. The motor 64 is actuated to rotate the rotor 56 moving the wafer 100 in a circular path through the process liquid in the ring section 70. With this movement, a subsequent holder 60 moves into the load port 54 to receive a subsequent wafer 100.

Process liquid may be jetted or sprayed from spray heads or nozzles 80, which may be submerged in or above the surface of the process liquid. The nozzles 80 may be aimed radially inwardly to provide a jet of liquid perpendicular to the wafer surface. Sonic energy may be introduced into the process liquid via one or more sonic transducers. As shown in FIG. 4, the nozzles 80 and sonic transducers 82, if used, may be positioned very close to the front side of the wafer (e.g., 5 to 25 or 50 mm) to enhance processing. The motor 64 rotates the rotor 56 at a rate that allows the wafer 100 to remain submerged in the process liquid for a time interval sufficient to complete processing the wafer, typically 1 to 30 minutes, corresponding to a rotation rate of 0.034 to 1 rpm. As the rotor 56 continues to rotate, the processed wafer 100 returns to the load port 54 and is removed from the process tank via the head 50. Subsequent wafers 100 are similarly processed.

Depending on the specific process and process liquid used, the wafer 100 may then be rinsed in the rinse chamber 36, to remove residual process liquid. Rinse liquid may be sprayed onto the wafer from rinse nozzles in the rinse chamber 36, and/or on the head 50. Generally the head 50 also spins the wafer 100 to fling off rinse liquid. In an optional second step performed within the clean housing 32, the head may lift the wafer 100 up into the clean chamber 34 where the wafer is further cleaned and/or dried. For applications such as photoresist strip where the process liquid is a solvent, the wafer 100 may be further cleaned and dried via the secondary chamber 48 such as a spin rinser dryer. The wafer 100 is then moved out of the enclosure 22 for further handling or processing.

The rotor 56 rotates about a rotation axis 66 which is substantially horizontal, i.e., within 15 degrees of horizontal. With the process tank 30 filled with process liquid, multiple wafers are simultaneously submerged in the process liquid, providing a relatively high throughput rate in a compact space. However, processing is uniform as each wafer is fully and equally exposed to the process liquid, as well as liquid jets and sonic energy, if used.

Generally, the surface of the process liquid in the process tank 30 is below the level of a holder aligned under the load port 54 so that the wafer is not submerged in or in contact with the bulk process liquid in the process tank 30 during hand off of the wafer between the head 50 and the holder 60. As shown in dotted lines in FIG. 3, a second load port 90 may optionally be provided on the process tank 30, to allow all loading to be performed at the load port 54 and all unloading to be performed at the second load port 90, or vice versa.

Operations of the system 20 and the process tank 30 are typically controlled via computer, to provide more uniform processing. The motor 64 may slowly and continuously rotate the rotor 56, except to pause momentarily while a wafer is loaded onto or removed from a holder 60 at the load port 54. In this way the wafers are generally continuously moving past any nozzles 80 or sonic transducers 82. Alternatively, the motor 64 may operate intermittently, rotating the rotor incrementally only as needed, so that the wafers are stationary within the process tank 30, except during momentary incremental movements for the wafer handoff. Generally, the rotor rotates only in one direction without reversing, and with the rotor pausing at least when each wafer holder moves to a load port in the process tank. The load port 54 may have a load port door movable from a first position wherein the load port door closes off and seals the load port, to a second position wherein the load port is open.

In the example shown, the rotor 56 has six arms 58 which are equally spaced apart and extend radially outward from the hub 62. In other designs, the rotor may have 3, 4, 5, 7, 8, 9 or 10 arms. In compact designs, the circumference of the outer wall 72 and the arm length are dependent on the diameter of the wafer 100. In the example shown for 300 mm diameter wafers, the outer wall 72 may have a diameter of about 1000 mm. The ratio of the wafer diameter to the inside diameter of the outer wall 72 may range from 0.1 or 0.2 to about 0.35. The ring section 70 has a width WW and a height HH sufficient to accommodate the wafer 100 and the holder 60 with adequate clearance, and to maximize the volume of the ring section 70 relative to the volume of the arm space 74 in the web section 76, and to reduce the total volume of process liquid used. The width WW of the ring section may be 2-20 times greater than the width of the arm slot of web section.

Although the rotor 56 in FIGS. 3 and 4 is shown with radial arms, other forms of rotors may be used, including a rotor having holders on a disk or ring instead of arms, or a rotor in the form of a round or polygonal cylinder or drum. The rotor may also be provided as an annular ring driven externally, with the central hub and arms omitted. Similarly, the rotor may be replaced entirely via a circular track in the tank, with individual holders advanced via a pushing mechanism.

A method for processing wafers includes at least partially filling a process tank with a process liquid, loading a first wafer onto a first holder, moving the first holder in a vertical circular path through the process tank, immersing the first holder into the process liquid, and similarly loading a second wafer onto a second holder, moving the second holder in the vertical circular path, following the first holder, and immersing the second holder into the process liquid. The first and second wafers are left immersed in the process liquid for a processing time interval sufficient to complete the processing step, e.g., 1-60 minutes. The vertical circular path is a path in a circle about a substantially horizontal axis. Of course, circle-like paths such as oval or elliptical paths, or polygonal paths may be used instead of a circular path.

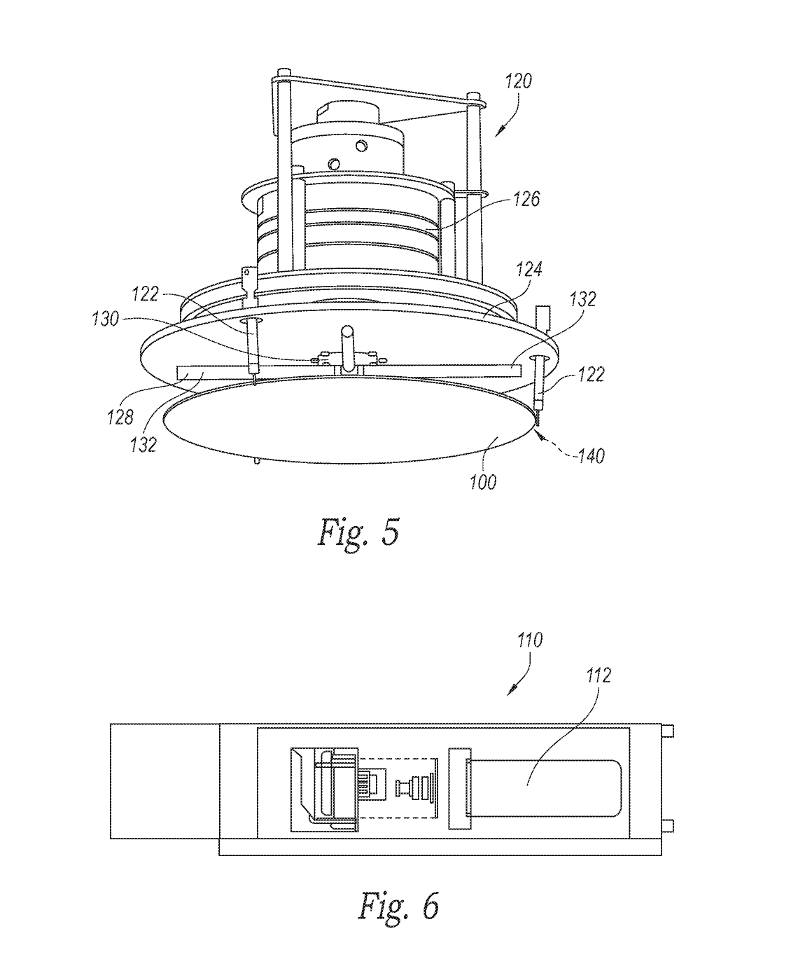

FIG. 5 shows an alternative head 120 similar to the head 50 and having fingers 122 for holding a wafer 100 at a wafer holding position generally shown at 140, typically several centimeters below the head plate 124 of the head 120. A head motor 126 on the head 120 rotates the head plate 124. Rinse arms 128 extend out from a rinse hub 130 attached to the frame of the head 120, which does not rotate. Rinse nozzles 132 on the rinse arms 128 are aimed at the wafer holding position. In use, with a wafer held in the wafer holding position, rinse liquid is pumped through the rinse hub 130 and the rinse arms 128 to the rinse nozzles, to rinse the up-facing front side of the wafer 100.

Where process gases or vapors are used instead of a process liquid, the orientation of the process tank 30 may be selected to better meet other design factors, such as height limitations, plumbing connections, etc. As shown in FIG. 6, the rotor in the process tank 30 may rotate about a substantially vertical axis, instead of the substantially horizontal axis as in FIGS. 1-4, as the direction of gravity has little or no effect in gas or vapor phase processing. The rotor may also optionally rotate about an axis between vertical and horizontal.

The methods and apparatus described are especially useful for time consuming process steps, as they allow multiple wafers to be processed simultaneously, while also achieving the benefits of single wafer processing. However, the present methods and apparatus may also be used in other ways as well. As used here, wafer refers collectively to silicon or other semiconductor material wafers, as well as other substrates on which micro-scale devices are formed.

Thus, novel apparatus and methods have been described. Various changes and substitutions may of course be made without departing from the spirit and scope of the invention. The invention, therefore, should not be limited, except to the following claims and their equivalents.

1. A wafer processor, comprising:
a process tank;
a rotor in the process tank;
a plurality of wafer holders on the rotor; and
a motor for rotating the rotor to move the wafer holders through the process tank.

2. The processor of claim 1 with the motor rotating the rotor in a first direction only, with the rotor pausing when each wafer holder moves to a load port in the process tank.

3. The processor of claim 1 with the process tank having a ring section and a web section, with the ring section having a width 2-20 times greater than the width of the arm slot.

4. The processor of claim 1 with the process tank having a ring section and a web section, and the rotor having a plurality of radial arms, with each radial arm extending from a central hub through the web section to a wafer holder.

5. The processor of claim 1 wherein the rotor is rotatable about a substantially horizontal axis.

6. The processor of claim 1 wherein the rotor is rotatable about a substantially vertical axis.

7. The processor of claim 1 further including a load port at a top of the process tank, and a clean housing at the load port, with the clean housing having an upper drain ring around an upper chamber and having a lower drain ring around a lower chamber below the upper chamber.

8. The processor of claim 1 with the process tank having an I-shaped cross section.

9. The processor of claim 4 with the ring section having an outer circumferential wall subtending an arc of at least 270 degrees.

10. The processor of claim 9 further including at least one spray nozzle on the outer circumferential wall adapted to spray liquid radially inwardly towards a wafer held in one of the wafer holders.

11. The processor of claim 9 further including at least one sonic transducer in the process tank.

12. The processor of claim 7 further including a head for holding a wafer, with the head movable vertically into the upper chamber and into the lower chamber.

13. The processor of claim 12 with the head including fingers for holding a wafer at a wafer holding position, and one or more rinse nozzles aimed at the wafer holding position.

14. The processor of claim 4 with the rotor having 4-8 arms and a single wafer holder at an outer end of each arm.

15. The processor of claim 7 with the process tank further including one or more liquid inlets and one or more gas inlets and a vacuum source at the load port.

16. The processor of claim 1 further comprising a process liquid in the process tank, with rotation of the rotor sequentially moving the wafer holders in a circular path into and out of the process liquid.

17. A wafer processor, comprising:
a process tank;
a rotor in the process tank;
a plurality of wafer holders on the rotor;
a motor for rotating the rotor to move the wafer holders in a circular path through the process tank;
the process tank having a ring section and a web section, and the rotor having a plurality of radial arms, with each radial arm extending from a central hub through the web section to a wafer holder;
at least one load port on the ring section; and
a load port door movable from a first position wherein the load port door closes off and seals the load port, to a second position wherein the load port is open.

18. The processor of claim 17 wherein the rotor is rotatable about a substantially vertical axis

19. A method for processing a wafer, comprising:
filling a process tank at partially with a process liquid;
loading a first wafer onto a first holder;
moving the first holder in a circular path through the process tank, immersing the first holder into the process liquid;
loading a second wafer onto a second holder;
moving the second holder in the circular path, following the first holder, and immersing the second holder into the process liquid; and
with the first and second wafers remaining immersed in the process liquid for a processing time interval.
